(19) United States
(12) Patent Application Publication
(10) Pub. No.: US 2023/0040109 A1
(43) Pub. Date: Feb. 9, 2023

(54) Epitaxial Wafer of Light-Emitting Chip, Method for Manufacturing Epitaxial Wafer, and Light-Emitting Chip

(71) Applicant: CHONGQING KONKA PHOTOELECTRIC TECHNOLOGY RESEARCH INSTITUTE CO., LTD., Chongqing (CN)

(72) Inventor: Yongxing LIU, Chongqing (CN)

(21) Appl. No.: 17/866,596

(22) Filed: Jul. 18, 2022

Related U.S. Application Data
(63) Continuation of application No. PCT/CN2021/110921, filed on Aug. 5, 2021.

(51) Int. Cl. H01L 33/06; H01L 33/14; H01L 33/00; H01L 33/32

(52) U.S. Cl. CPC H01L 33/06; H01L 33/14; H01L 33/0075; H01L 33/32

(57) ABSTRACT

An epitaxial wafer of a light-emitting chip, a method for manufacturing an epitaxial wafer, and a light-emitting chip are provided. A light-emitting layer (5) of an active region of the epitaxial wafer of the light-emitting chip includes at least one superlattice (51), and each superlattice includes: a quantum well sub-layer (511) and a stress conversion sub-layer (512) which is formed on the quantum well sub-layer (511) and enables the quantum well sub-layer (511) to be converted from compressive strain to tensile strain, and the stress conversion sub-layer (512) and the quantum well sub-layer (511) form a two-dimensional electron gas.

### CROSS REFERENCE

This application is a National Stage Filing of the PCT International Application No. PCT/CN2021/110921 filed on Aug. 5, 2021, the entirety of which is herein incorporated by reference.

### TECHNICAL FIELD

The present disclosure relates to the field of light-emitting chips, and in particular to an epitaxial wafer of a light-emitting chip, a method for manufacturing an epitaxial wafer, and a light-emitting chip.

### BACKGROUND

The Micro Light-Emitting Diode (Micro LED) technology is an LED miniaturization and matrixing technology, which is an ultimate development form of Mini LED and is also a next-generation revolutionary display technology. A Micro LED chip has a size of 1 to 10 μm, and can address each pixel individually and drive light emission individually as in an Organic Light-Emitting Diode (OLED). The Micro LED technology has advantages such as low power consumption, high brightness, ultrahigh resolution and color saturation, high response speed, and long service life.

Although the Micro LED has significant advantages, the technical challenges are great. Although the Mini LED is initially considered as a transitional stage in the evolution of display technology towards the Micro LED, the Micro LED has greater technical challenges. One of the challenges is that as the size of the chip decreases, the light-emitting efficiency decreases correspondingly, especially, the light-emitting efficiencies of a green LED chip and a red LED chip are far lower than that of a blue LED chip.

Therefore, how to improve the light-emitting efficiency of the LED chip is a problem urgently needed to be solved at present.

### SUMMARY

In view of the above deficiencies of the related art, embodiments of the present disclosure provide an epitaxial wafer of a light-emitting chip, a method for manufacturing an epitaxial wafer, and a light-emitting chip, which can solve the problem that the light-emitting efficiency of a light-emitting chip is low in the related art.

The embodiments of the present disclosure provide an epitaxial wafer of a light-emitting chip, including: a light-emitting layer of an active region, where the light-emitting layer of the active region includes at least one superlattice, each superlattice including:
a quantum well sub-layer;
a stress conversion sub-layer, which is formed on the quantum well sub-layer and enables the quantum well sub-layer to be converted into tensile strain from compressive strain, wherein the stress conversion sub-layer and the quantum well sub-layer form a two-dimensional electron gas.

According to the epitaxial wafer of the light-emitting chip, the light-emitting layer of the active region is of a superlattice structure, each superlattice includes a quantum well sub-layer and a stress conversion sub-layer, which is formed on the quantum well sub-layer and enables the quantum well sub-layer to be converted into tensile strain from compressive strain, so that the well width is increased, and the crystal quality is improved. Meanwhile, the stress conversion sub-layer and the quantum well sub-layer form the two-dimensional electron gas, so that the local area has more electrons, then the density of current carriers in a thin layer is obviously improved, therefore, the radiation recombination probability is improved, and the light-emitting efficiency is improved.

On the basis of the same inventive concept, the embodiments of the present disclosure also provide a light-emitting chip, which includes the epitaxial wafer of the light-emitting chip as described above, the epitaxial wafer of the light-emitting chip further includes a first current spreading layer and a second current spreading layer respectively formed on an upper side and a lower side of the light-emitting layer of the active region, and the light-emitting chip further includes a first electrode and a second electrode respectively electrically connected to the first current spreading layer and the second current spreading layer.

The light-emitting chip adopts the epitaxial wafer of the light-emitting chip with better crystal quality and higher light-emitting efficiency, so that the light-emitting efficiency of the light-emitting chip is higher.

On the basis of the same inventive concept, the embodiments of the present disclosure also provide a method for manufacturing an epitaxial wafer of a light-emitting chip, including: a light-emitting layer of an active region is grown, which includes that at least one superlattice is grown by the following operations:
the quantum well sub-layer is grown in a reaction chamber; and
the stress conversion sub-layer is grown on the quantum well sub-layer.

According to the method for manufacturing the epitaxial wafer of the light-emitting chip, the manufacturing process is simple and efficient. Moreover, the light-emitting layer of the active region of the manufactured epitaxial wafer of the light-emitting chip is of a superlattice structure, each superlattice includes the quantum well sub-layer and the stress conversion sub-layer, which is formed on the quantum well sub-layer and enables the quantum well sub-layer to be converted into tensile strain from compressive strain, so that the well width is increased, and the crystal quality is improved. Meanwhile, the stress conversion sub-layer and the quantum well sub-layer form the two-dimensional electron gas, so that the local area has more electrons, then the density of current carriers in a thin layer is obviously improved, therefore, the radiation recombination probability is improved, and the light-emitting efficiency is improved.

### BRIEF DESCRIPTION OF THE DRAWINGS

FIG. 1 is a schematic structure diagram of an epitaxial wafer of a light-emitting chip provided by an embodiment of the present disclosure.

FIG. 2 is a schematic structure diagram I of a superlattice provided by an embodiment of the present disclosure.

FIG. 3(a) is a schematic diagram of a lattice under compressive strain provided by an embodiment of the present disclosure.

FIG. 3(b) is a schematic diagram of a lattice under tensile strain provided by an embodiment of the present disclosure.

FIG. 4 is a schematic structure diagram II of a superlattice provided by an embodiment of the present disclosure.

FIG. 5 is a schematic structure diagram III of a superlattice provided by an embodiment of the present disclosure.

FIG. 6 is a schematic structure diagram IV of a superlattice provided by an embodiment of the present disclosure.

FIG. 7 is a schematic structure diagram V of a superlattice provided by an embodiment of the present disclosure.

FIG. 8 is a schematic structure diagram VI of a superlattice provided by an embodiment of the present disclosure.

FIG. 9 is a schematic flow chart of a method for manufacturing an epitaxial wafer of a light-emitting chip provided by another exemplary embodiment of the present disclosure.

FIG. 10 is a schematic diagram of pulse-based control provided by another exemplary embodiment of the present disclosure.

FIG. 11 is a schematic structure diagram I of an epitaxial wafer of a light-emitting chip provided by another exemplary embodiment of the present disclosure.

FIG. 12 is a schematic structure diagram II of an epitaxial wafer of a light-emitting chip provided by another exemplary embodiment of the present disclosure.

FIG. 13 is a schematic structure diagram III of an epitaxial wafer of a light-emitting chip provided by another embodiment of the present disclosure.

FIG. 14 is a schematic structure diagram IV of an epitaxial wafer of a light-emitting chip provided by another exemplary embodiment of the present disclosure.

FIG. 15 is a schematic structure diagram V of an epitaxial wafer of a light-emitting chip provided by another exemplary embodiment of the present disclosure.

FIG. 16 is a schematic structure diagram VI of an epitaxial wafer of a light-emitting chip provided by another exemplary embodiment of the present disclosure.

FIG. 17 is a schematic structure diagram VII of an epitaxial wafer of a light-emitting chip provided by another exemplary embodiment of the present disclosure.

### DESCRIPTION OF REFERENCE SIGNS

1, substrate; 2, stress control layer; 3, second current spreading layer; 4, preparation layer of an active region; 5, light-emitting layer of an active region; 51, superlattice; 511, quantum well sub-layer; 512, stress conversion sub-layer; 513, GaN cap layer; 514, stress compensation sub-layer; 515, Al_{b}Ga_{1-b}N cap layer; 6, electron blocking layer; 7, first current spreading layer; and 8, first ohmic contact layer.

### DETAILED DESCRIPTION OF THE EMBODIMENTS

In order to facilitate an understanding of the present disclosure, a more complete description of the present disclosure will now be made with reference to the associated drawings. Preferred implementations of the present disclosure are given in the drawings. However, the present disclosure may be realized in many different forms and is not limited to the implementations described herein. Rather, the implementations are provided so that a more thorough and complete understanding of the content of the present disclosure is provided.

Unless otherwise defined, all technical and scientific terms used in the specification have a same meaning generally understood by a person having ordinary skill in the art to which the present disclosure belongs. The terms used in the specification of the present disclosure herein are for the purpose of describing the specific implementations only and are not intended to be limiting of the present disclosure.

In the related art, as the size of a chip decreases, the light-emitting efficiency decreases correspondingly, especially the light-emitting efficiencies of a green LED chip and a red LED chip are far lower than that of a blue LED chip.

Based on this, the present disclosure provides a solution capable of solving the above technical problem, the details of which will be set forth in the following embodiments.

The embodiments provide an epitaxial wafer of a light-emitting chip, which may be used for manufacturing a micron-sized light-emitting chip, for example, a Mini LED chip or a Micro LED chip, and may also be used for manufacturing a common-sized LED chip or a large-sized LED chip with the size greater than 50 microns. In addition, the epitaxial wafer of the light-emitting chip may be used for manufacturing, but not limited to, a flip light-emitting chip, a vertical light-emitting chip, or a forward light-emitting chip.

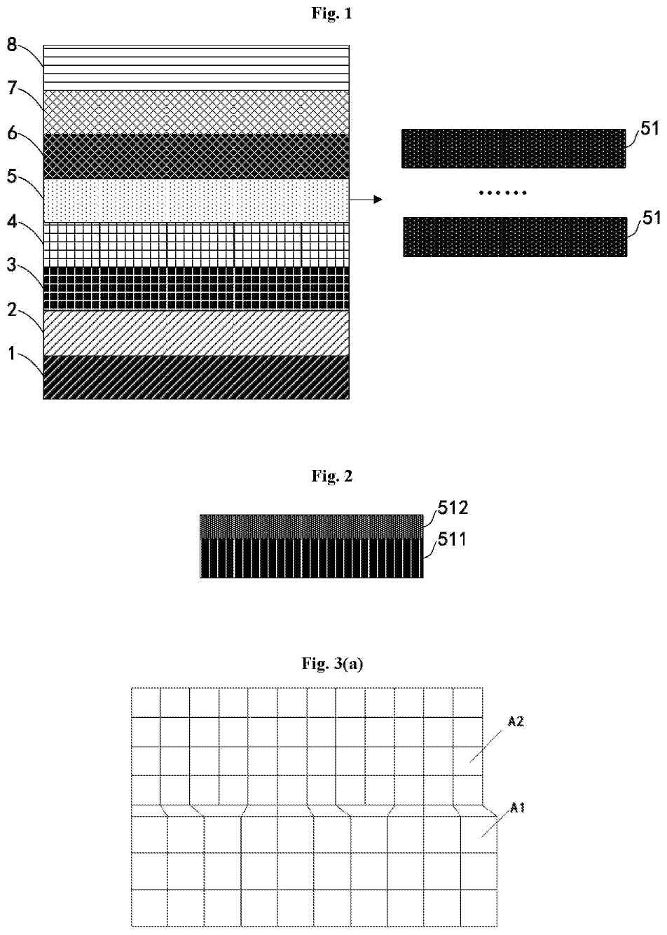

As shown in FIG. 1, the epitaxial wafer of the light-emitting chip in the embodiment includes a light-emitting layer 5 of an active region, the light-emitting layer 5 of the active region in the embodiment includes at least one superlattice 51, namely, the light-emitting layer 5 of the active region comprises a plurality of quantum well superlattices. It should be understood that the number of superlattices 51 included in the light-emitting layer 5 of the active region in the embodiment may be flexibly set according to application requirements, for example, one superlattice 51 may be included, or two or more superlattices 51 can be included, and the at least two superlattices are sequentially stacked in a direction from bottom to top.

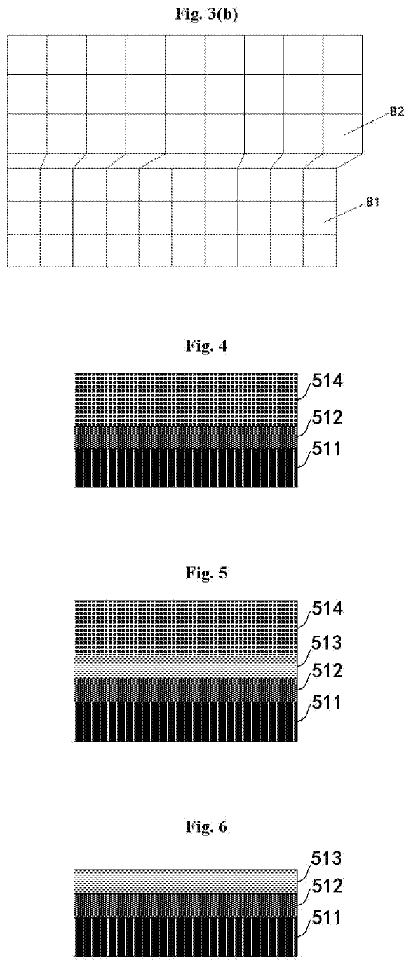

As shown in FIG. 2, the superlattice 51 in the embodiment includes a quantum well sub-layer 511 and a stress conversion sub-layer 512 formed on the quantum well sub-layer. The arrangement of the stress conversion sub-layer 512 enables the quantum well sub-layer 511 to be converted into tensile strain from compressive strain, so that the well width is increased, and the crystal quality and the performance of a device are improved. For example, as shown in FIG. 3(a), under compressive strain, a later-formed lattice A2 is compressed relative to a previously-formed lattice A1 in the epitaxy process. As shown in FIG. 3(b), under tensile strain, a later-formed lattice B2 is in a stretched state relative to a previously-formed lattice B1 in the epitaxy process, so that the well width is increased, and the crystal quality and the performance of a device are improved.

Meanwhile, in the embodiment, the stress conversion sub-layer 512 and the quantum well sub-layer 511 form two-dimensional electron gas, so that the local area has more electrons, then the density of current carriers in a thin layer is obviously improved, therefore, the radiation recombination probability is improved, and the light-emitting efficiency is improved. In an example of the embodiment, a two-dimensional electron system refers to a system in which the movement of a group of electrons in one direction is limited to a small range, while being free to move in the other two directions. If the density of electrons in the two-dimensional electron system is low, this two-dimensional electron system is called the two-dimensional electron gas.

It should be understood that in the embodiment, the specific materials, sizes, and the like of the quantum well sub-layer 511 and the stress conversion sub-layer 512 may be flexibly set according to application requirements as long as the above conditions are satisfied. For example, the quantum well sub-layer 511 may include, but is not limited to, an InₓGa₁₋ₓN sub-layer, where In is indium, Ga is gallium, and N is nitrogen. The stress conversion sub-layer 512 includes an Al_{y}Sc_{1-y}N sub-layer formed on the InₓGa₁₋ₓN sub-layer, where Al is aluminum, and Sc is scandium.

It should be understood that in the embodiment, the thickness of the Al_{y}Sc_{1-y}N sub-layer and the thickness of the InₓGa₁₋ₓN sub-layer may be flexibly set according to specific application requirements, and the thickness of the Al_{y}Sc_{1-y}N sub-layer and the thickness of the InₓGa₁₋ₓN sub-layer may be the same or different. For example, in an application scenario, the thickness of the Al_{y}Sc_{1-y}N sub-layer is greater than or equal to 0.5 nm and smaller than or equal to 3 nm, for example, the specific value can be, but not limited to, 0.5 nm, 1 nm, 1.5 nm, 2 nm, 3 nm, or the like. The thickness of the InₓGa₁₋ₓN sub-layer is greater than or equal to 1 nm and smaller than or equal to 5 nm, for example, the specific value can be, but not limited to, 1 nm, 1.5 nm, 2.5 nm, 3.5 nm, 4.5 nm, 5 nm, or the like.

In some application examples of the embodiment, in a case where the quantum well sub-layer 511 is the InₓGa₁₋ₓN sub-layer, a value of x of InₓGa₁₋ₓN satisfies a following equation (1):

1240=λ×(3.42−2.65×(1−x)−2.4×x×(1−x) (1)

The above equation (1) can be deduced by combining the following equation (2) and equation (3):

Eg=3.42−2.65×(1−x)−2.4×x×(1−x) (2)

λ=1240/Eg (3)

In the above equations, Eg is band gap energy, and λ is light-emitting wavelength, namely, the light-emitting wavelength of the epitaxial wafer of the light-emitting chip. That is, in the embodiment, the value of x of InₓGa₁₋ₓN may be determined and set according to the light-emitting color of the epitaxial wafer of the light-emitting chip. For example, in an application scenario, the value of λ may be greater than or equal to 400 nm and smaller than or equal to 740 nm. That is, the light-emitting color is between blue light and red light. For example, in some application scenarios of the embodiment, a red light-emitting chip and/or a green light-emitting chip may be set to adopt the epitaxial layer of the light-emitting chip provided by the embodiment, so that the light-emitting efficiency is higher. Meanwhile, in a case where the thickness of the red light-emitting chip and/or the green light-emitting chip is the same as that of the blue light-emitting chip, the light-emitting efficiency of the red light-emitting chip and/or the green light-emitting chip is enabled to be the same as that of the blue light-emitting chip, so that the display effect of a display assembly and the light-emitting effect of a light-emitting assembly prepared by using the red light-emitting chip, the blue light-emitting chip and the green light-emitting chip are further improved.

In an application example of the embodiment, the stress conversion sub-layer 512 is the Al_{y}Sc_{1-y}N sub-layer, a value of y of Al_{y}Sc_{1-y}N is greater than 0 and smaller than 1, for example, the specific value of y may be, but not limited to, 0.1, 0.2, 0.3, 0.5, 0.8, 0.9, 1, or the like.

In another example of the embodiment, referring to FIG. 4, the superlattice 51 may further include a stress compensation sub-layer 514 formed on the Al_{y}Sc_{1-y}N sub-layer (namely, the stress conversion sub-layer 512). The stress compensation sub-layer 514 can effectively compensate for stress, so that the crystal quality of a quantum well can be further improved. In the example, the material and size of the stress compensation sub-layer 514 may be flexibly set according to application requirements, as long as effective stress compensation can be achieved to improve the crystal quality of the quantum well.

For example, in an application example, the stress compensation sub-layer 514 includes an Al_{z}Ga_{1-z}N:Si sub-layer, where the concentration of Si is in a range from 0 cm⁻³ to 1×10¹⁸ cm⁻³. For example, in a case where the concentration of Si is 0 cm⁻³, the stress compensation sub-layer 514 may be Al_{z}Ga_{1-z}N; and in a case where the concentration of Si is greater than 0 cm⁻³ and smaller than 1×10¹⁸ cm⁻³, the stress compensation sub-layer 514 is Al_{z}Ga_{1-z}N:Si.

In an application example, the stress compensation sub-layer 514 is the Al_{z}Ga_{1-z}N:Si sub-layer, where a value of z of Al_{z}Ga_{1-z}N is greater than or equal to 0 and smaller than or equal to 0.4, for example, the value of z may be 0.1, 0.15, 0.2, 0.25, 0.3, 0.4, or the like.

In an application example, the thickness of the Al_{z}Ga_{1-z}N:Si sub-layer is greater than or equal to 6.5 nm and smaller than or equal to 20 nm, and the specific value may be flexibly set according to application requirements, for example, can be but not limited to, 6.5 nm, 8 nm, 9 nm, 10 nm, 12 nm, 15 nm, 18 nm, 20 nm or the like.

In another example of the embodiment, referring to FIG. 5, the superlattice 51 may further include a GaN cap layer 513 formed between the Al_{y}Sc_{1-y}N sub-layer and the Al_{z}Ga_{1-z}N:Si sub-layer. The GaN cap layer 513 can cover flaws such as Pit, thereby further improving the crystal quality.

In the embodiment, the thickness of the GaN cap layer 513 may be flexibly set according to specific application requirements, for example, the thickness of the GaN cap layer 513 is greater than or equal to 1 nm and smaller than or equal to 3 nm, for example, the specific value of the thickness can be, but not limited to, 1 nm, 1.5 nm, 2 nm, 2.5 nm, 3 nm or the like.

In another example of the embodiment, referring to FIG. 6, the superlattice 51 may consist of the quantum well sub-layer 511, the stress conversion sub-layer 512, and the GaN cap layer 513. Alternatively, the superlattice 51 may include the quantum well sub-layer 511, the stress conversion sub-layer 512, and the GaN cap layer 513, but does not include the stress compensation sub-layer 514.

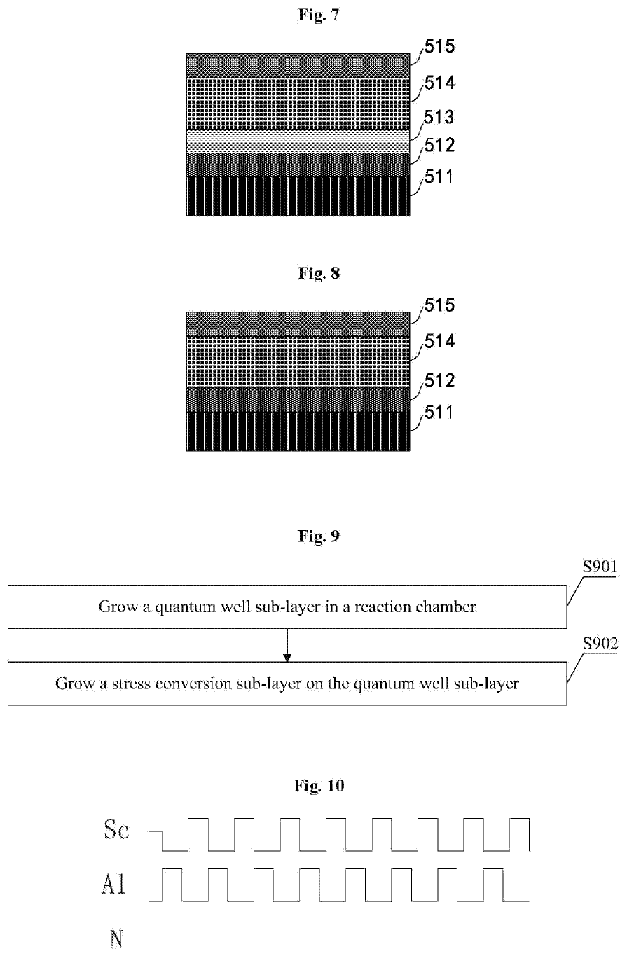

In another example of the embodiment, referring to FIG. 7, the superlattice 51 further includes an Al_{b}Ga_{1-b}N cap layer 515 formed on the Al_{z}Ga_{1-z}N:Si sub-layer, where b is greater than or equal to 0, and smaller than the value of z, that is, the value of z is greater than or equal to 0, b is smaller than z, and z is smaller than or equal to 0.4. The specific values of b and z may be flexibly set according to specific application scenarios, and no elaboration will be made here.

The thickness of the Al_{b}Ga_{1-b}N cap layer 515 may be flexibly set according to specific application requirements, for example, the value of thickness of the AlbGa1−bN cap layer 515 is greater than or equal to 1 nm and smaller than or equal to 3 nm, the specific value may be flexibly set according to specific application scenarios, and no elaboration will be made herein.

In another example of the embodiment, referring to the superlattice 51 shown in FIG. 8, the GaN cap layer 513 is omitted compared with the superlattice 51 shown in FIG. 7.

In some examples of the embodiment, referring to FIG. 1, the epitaxial wafer of the light-emitting chip may further include a substrate 1, a second current spreading layer 3 disposed between the substrate 1 and the light-emitting layer 5 of the active region, and a first current spreading layer 7 disposed on the light-emitting layer 5 of the active region. The first current spreading layer 7 may be an N-type current spreading layer and the second current spreading layer 3 may be a P-type current spreading layer, or the first current spreading layer 7 may be a P-type current spreading layer and the second current spreading layer 3 may be an N-type current spreading layer.

In some examples of the embodiment, referring to FIG. 1, the epitaxial wafer of the light-emitting chip may further include at least one of: a stress control layer 2 disposed between the substrate 1 and the second current spreading layer 3, a preparation layer of an active region disposed between the second current spreading layer 3 and the light-emitting layer 5 of the active region, an electron blocking layer 6 disposed between the light-emitting layer 5 of the active region and the first current spreading layer 7, and a first ohmic contact layer 8 disposed on the first current spreading layer 7. It should be understood that the materials, the sizes, the growth modes and the like of the substrate 1, the stress control layer 2, the second current spreading layer 3, the preparation layer 4 of the active region, the electron blocking layer 6 and the first ohmic contact layer 8 of the epitaxial wafer of the light-emitting chip may be flexibly set, and the embodiment does not have any limitations on the materials, the sizes and the growth modes. For example, an explanatory epitaxial wafer of a light-emitting chip includes, as shown below, in sequence from bottom to top:
Substrate 1: sapphire substrate
Stress control layer 2: no GaN layer is doped.
Second current spreading layer 3: GaN:Si, and the concentration of Si is 1×10¹⁷ cm⁻³−1×10²⁰ cm⁻³.
A preparation layer 4 of an active region: InGaN/GaN:Si superlattice, and the concentration of Si is 1×10¹⁶ cm⁻³−1×10¹⁸ cm⁻³.
Quantum well sub-layer 511: InₓGa₁₋ₓN
Stress conversion sub-layer 512: Al_{y}Sc_{1-y}N
GaN cap layer 513;
Stress compensation sub-layer 514: Al_{z}Ga_{1-z}N:Si, and the concentration of Si is in a range from 0 cm⁻³ to 1×10¹⁸ cm⁻³.
Al_{b}Ga_{1-b}N cap layer 515
Electron blocking layer 6: AlGaN:Mg, and the doping concentration of Mg is 1×10¹⁷ cm⁻³−1×1020 cm⁻³.
First current spreading layer 7: GaN:Mg, and the doping concentration of Mg is 1×10¹⁷ cm⁻³−1×10²⁰ cm⁻³.
First ohmic contact layer 8: InGaN:Mg, and the doping concentration of Mg is 1×10¹⁷ cm⁻³−1×10¹⁹ cm⁻³.

Therefore, on the basis of including the quantum well sub-layer 511 and the stress conversion sub-layer 512, the epitaxial wafer of the light-emitting chip provided by the embodiment may further flexibly include any combination of the GaN cap layer 513, the stress compensation sub-layer 514, and the Al_{b}Ga_{1-b}N cap layer 515 according to specific application requirements, and has at least the following advantages.

The longer the light-emitting wavelength of the epitaxial wafer of the light-emitting chip is, the larger the value of x of the In component of the quantum well sub-layer 511 (for example, InₓGa₁₋ₓN sub-layer) is, the lower the growth temperature is, and the easier it is to generate the defects of obvious lattice mismatch and Stark quantum confinement effect. The stress conversion sub-layer 512 (for example, AlScN sub-layer) converts InGaN from compressive strain to tensile strain, so that the crystal quality is improved, and meanwhile, the pulling effect of tensile stress results in InGaN with higher In component.

Meanwhile, the stress conversion sub-layer 512 (for example, AlScN sub-layer) can prevent InGaN with high In component from decomposing when a barrier layer is grown at a high temperature, thereby forming InGaN with higher In component.

The stress compensation sub-layer 514 (for example, AlGaN sub-layer) can effectively compensate for stress, so that the crystal quality of a quantum well can be further improved.

The quantum well sub-layer 511 (for example, InₓGa₁₋ₓN sub-layer) and the stress conversion sub-layer 512 (for example, AlScN sub-layer) form two-dimensional electron gas, so that the local area has more electrons, then the density of current carriers in a thin layer is obviously improved, therefore, the radiation recombination probability is improved, and the light-emitting efficiency is improved.

### ANOTHER EXEMPLARY EMBODIMENT

For ease of understanding, the embodiment will be described below with a method for manufacturing an epitaxial layer of a light-emitting chip as an example. The method for manufacturing the epitaxial wafer of the light-emitting chip includes: a light-emitting layer of an active region is grown, and the operation that the light-emitting layer of the active region is grown includes that at least one superlattice is grown by the following operation as shown in FIG. 9.

At S901, a quantum well sub-layer is grown in a reaction chamber.

It should be understood that the quantum well sub-layer in the embodiment may adopt various growth manners of the quantum well sub-layer, and the embodiment does not limit the adopted growth manners.

For example, the quantum well sub-layer is the InₓGa₁₋ₓN sub-layer, the thickness value TH1is set to be 1 nm≤TH1≤5 nm. When the InₓGa₁₋ₓN sub-layer is grown in the reaction chamber, the temperature in the reaction chamber, namely, the growth temperature T1 is 650° C.≤T1≤850° C., meanwhile, an In source, a Ga source and an N source are introduced into the reaction chamber, and nitrogen is taken as a carrier gas. In the embodiment, the In source and the Ga source may be flexibly selected, for example, the In source may include, but is not limited to, trimethylindium (TMIn), and the Ga source may include, but is not limited to, trimethylgallium (TMGa) or triethylgallium (TEGa); and the N source may include, but is not limited to, ammonia NH₃. In an example, NH₃ may be commonly introduced into the reaction chamber, and nitrogen may be used as a carrier gas to introduce the In source and the Ga source to form the InₓGa₁₋ₓN sub-layer.

At S902, a stress conversion sub-layer is grown on the quantum well sub-layer.

It should be understood that the stress conversion sub-layer in the embodiment may adopt various growth manners of the stress conversion sub-layer, and the embodiment does not limit the growth manners.

For example, in a case where the stress conversion sub-layer is the Al_{y}Sc_{1-y}N sub-layer, the thickness value TH2 is set to be 0.5 nm≤TH2≤3 nm. When the Al_{y}Sc_{1-y}N sub-layer is grown on the InₓGa₁₋ₓN sub-layer in the reaction chamber, the temperature in the reaction chamber, namely, the growth temperature T2 may be the same as T1, or may be greater than T1, namely, 650° C.≤T1≤T2≤1250° C., meanwhile, an In source, a Sc source and an N source are introduced into the reaction chamber, and nitrogen or hydrogen is taken as a carrier gas. In the embodiment, the Al source and the Sc source may be flexibly selected, for example, the Al source may include, but is not limited to, trimethylaluminum (TMAl), and the Sc source may include, but is not limited to, tricyclopentadienyl scandium Cp₃Sc; and the N source may include, but is not limited to, ammonia NH₃. In an example, NH₃ may be commonly introduced into the reaction chamber, and nitrogen or hydrogen may be used as a carrier gas to introduce the Al source and the Sc source to form the Al_{y}Sc_{1-y}N sub-layer.

In an application example of the embodiment, the operation that the stress conversion sub-layer is grown on the quantum well sub-layer may include: an N source is injected into the reaction chamber, and a Sc source and an Al source are alternately injected according to a set proportion. For example, NH₃ may be constantly introduced into the reaction chamber, and nitrogen or hydrogen may be used as a carrier gas to alternately introduce the Al source and the Sc source according to a set proportion. The value of set proportion may be flexibly set according to specific application requirements. For example, referring to FIG. 10, nitrogen or hydrogen may be used as a carrier gas to alternately introduce the Al source and the Sc source according to the set proportion by, but not limited to, a pulse method. In FIG. 10, the N source is constantly introduced, and the Sc source and Al source are injected into the reaction chamber according to pulsed colloids as shown in the figure.

In the embodiment, in a case where the superlattice includes the GaN cap layer, the GaN cap layer may adopt various growth manners of the GaN cap layer, and the embodiment does not limit the growth manners. For example, the thickness TH3 is set to be 1 nm≤TH3≤3 nm. When the GaN cap layer is grown on the Al_{y}Sc_{1-y}N sub-layer in the reaction chamber, the temperature in the reaction chamber, namely, the growth temperature T3 may be the same as or different from T3 described above, and may be flexibly set according to specific application requirements. A small amount of Ga source and N source are introduced into the reaction chamber.

In the embodiment, in a case where the superlattice includes the stress compensation sub-layer, for example, the Al_{z}Ga_{1-z}N:Si sub-layer, the Al_{z}Ga_{1-z}N:Si sub-layer may adopt various growth manners of the Al_{z}Ga_{1-z}N:Si sub-layer, and the embodiment does not limit the growth manners. For example, the thickness TH4 is set to be 6.5 nm≤TH4≤20 nm. When the Al_{z}Ga_{1-z}N:Si sub-layer is grown on the GaN cap layer in the reaction chamber, the temperature in the reaction chamber, namely, the growth temperature T4 may be, but not limited to 800° C.≤T4≤1100° C., the doping concentration of Si is shown in the above examples, and no elaboration will be made here.

In the embodiment, in a case where the superlattice includes the Al_{b}Ga_{1-b}N cap layer, the Al_{b}Ga_{1-b}N cap layer can adopt various growth manners of the Al_{b}Ga_{1-b}N cap layer, and the embodiment does not limit the growth manners. For example, the thickness value TH5 is set to be 0 nm≤TH5≤3 nm. When the Al_{b}Ga_{1-b}N cap layer is grown on the Al_{z}Ga_{1-z}N:Si sub-layer in the reaction chamber, the temperature in the reaction chamber, namely, the growth temperature T5 can be, but not limited to 800° C.≤T4≤1100° C., namely, T5 and T4 may be the same or also may be different, and no more elaboration will be made herein.

In the embodiment, the epitaxial wafer of the light-emitting chip may further include at least one of a substrate, a stress control layer, a second current spreading layer, a preparation layer of an active region, an electron blocking layer, a first current spreading layer, and a first ohmic contact layer. The specific growth modes of the above layers may adopt, but are not limited to, existing various growth modes, and no more elaboration will be made herein.

According to the manufacturing method in the above samples of the embodiment, the manufacturing process of the epitaxial wafer of the light-emitting chip is simple and efficient. Moreover, the light-emitting layer of the active region of the manufactured epitaxial wafer of the light-emitting chip is of a superlattice structure, each superlattice includes the quantum well sub-layer and the stress conversion sub-layer, which is formed on the quantum well sub-layer and enables the quantum well sub-layer to be converted into tensile strain from compressive strain, so that the well width is increased, and crystal quality is improved. Meanwhile, the stress conversion sub-layer and the quantum well sub-layer form the two-dimensional electron gas, so that the local area has more electrons, then the density of current carriers in a thin layer is obviously improved, therefore, the radiation recombination probability is improved, and the light-emitting efficiency is improved.

### ANOTHER EXEMPLARY EMBODIMENT

The embodiments provide a light-emitting chip, which may be, but not limited to, a Mini LED chip or a Micro LED chip, or a common-sized LED with the size greater than 50 microns. The light-emitting chip may be, but not limited to, a flip light-emitting chip, a vertical light-emitting chip, or a forward light-emitting chip. The light-emitting chip includes the epitaxial wafer of the light-emitting chip described by the above embodiments. The epitaxial wafer of the light-emitting chip further includes a first current spreading layer and a second current spreading layer respectively formed on an upper side and a lower side of the light-emitting layer of the active region, and the light-emitting chip further includes a first electrode and a second electrode respectively electrically connected to the first current spreading layer and the second current spreading layer.

In an example, referring to FIG. 11, the epitaxial wafer of the light-emitting chip included by the light-emitting chip includes a substrate 1, a stress control layer 2, a second current spreading layer 3, a preparation layer of an active region 4, a superlattice 51, an electron blocking layer 6, a first current spreading layer 7, and a first ohmic contact layer 8, where the superlattice 51 includes a quantum well sub-layer 511: InₓGa₁₋ₓN and a stress conversion sub-layer 512: Al_{y}Sc_{1-y}N.

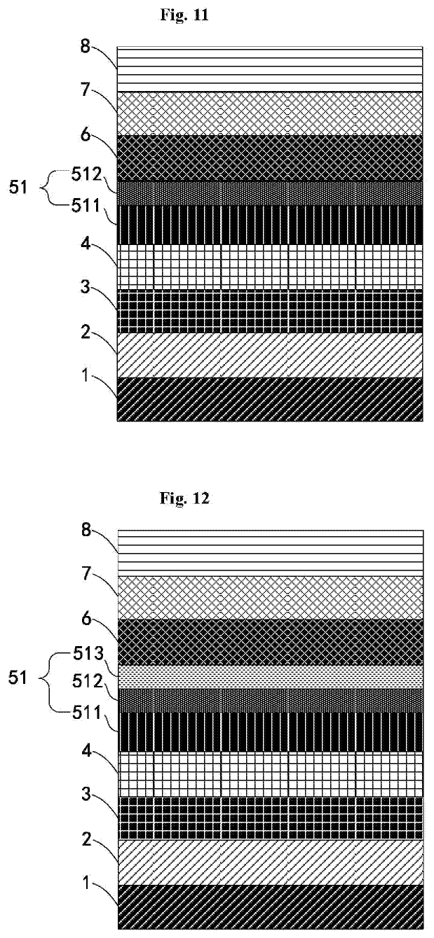

In another example, referring to FIG. 12, the epitaxial wafer of the light-emitting chip included by the light-emitting chip includes a substrate 1, a stress control layer 2, a second current spreading layer 3, an preparation layer of an active region 4, a superlattice 51, an electron blocking layer 6, a first current spreading layer 7, and a first ohmic contact layer 8, where the superlattice 51 includes a quantum well sub-layer 511: InₓGa₁₋ₓN a stress conversion sub-layer 512: Al_{y}Sc_{1-y}N and a GaN cap layer 513.

In another example, referring to FIG. 13, the epitaxial wafer of the light-emitting chip included by the light-emitting chip includes a substrate 1, a stress control layer 2, a second current spreading layer 3, an preparation layer of an active region 4, a superlattice 51, an electron blocking layer 6, a first current spreading layer 7, and a first ohmic contact layer 8, where the superlattice 51 includes a quantum well sub-layer 511: InₓGa₁₋ₓN, a stress conversion sub-layer 512: Al_{y}Sc_{1-y}N, and a stress compensation sub-layer 514: Al_{z}Ga_{1-z}N:Si, and the concentration of Si is in a range from 0 cm⁻³ to 1×10¹⁸ cm⁻³.

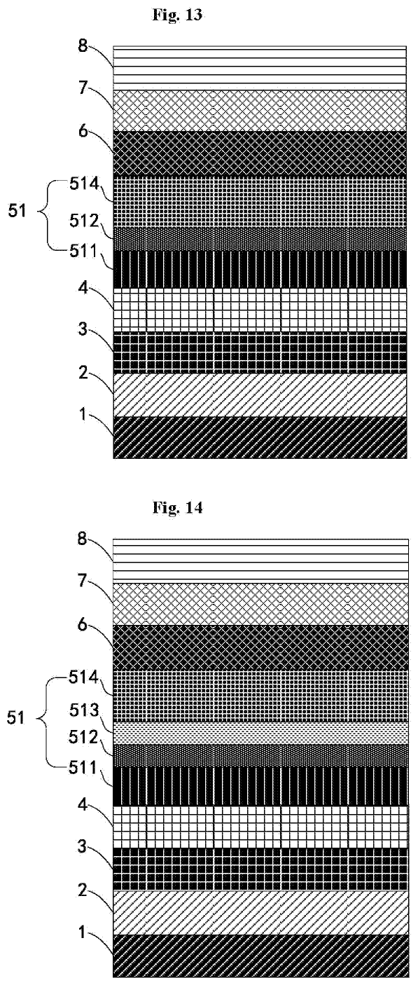

In another example, referring to FIG. 14, the epitaxial wafer of the light-emitting chip included by the light-emitting chip includes a substrate 1, a stress control layer 2, a second current spreading layer 3, an preparation layer of an active region 4, a superlattice 51, an electron blocking layer 6, a first current spreading layer 7, and a first ohmic contact layer 8, where the superlattice 51 includes a quantum well sub-layer 511: InₓGa₁₋ₓN, a stress conversion sub-layer 512: Al_{y}Sc_{1-y}N, a GaN cap layer 513 and a stress compensation sub-layer 514: Al_{z}Ga_{1-z}N:Si, and the concentration of Si is in a range from 0 cm⁻³ to 1×10¹⁸ cm⁻³.

In another example, referring to FIG. 15, the epitaxial wafer of the light-emitting chip included by the light-emitting chip includes a substrate 1, a stress control layer 2, a second current spreading layer 3, an preparation layer of an active region 4, a superlattice 51, an electron blocking layer 6, a first current spreading layer 7, and a first ohmic contact layer 8, where the superlattice 51 includes a quantum well sub-layer 511: InₓGa₁₋ₓN, a stress conversion sub-layer 512: Al_{y}Sc_{1-y}N, a stress compensation sub-layer 514: Al_{z}Ga_{1-z}N:Si, and an Al_{b}Ga_{1-b}N GaN cap layer 515.

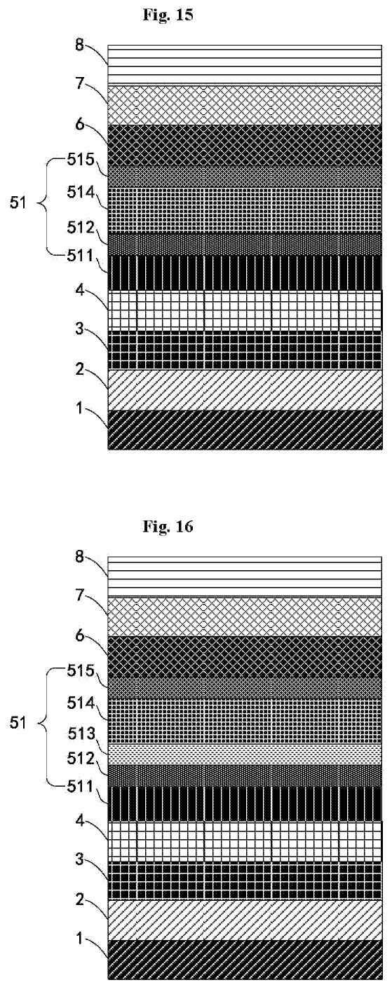

In another example, referring to FIG. 16, the epitaxial wafer of the light-emitting chip included by the light-emitting chip includes a substrate 1, a stress control layer 2, a second current spreading layer 3, an preparation layer of an active region 4, a superlattice 51, an electron blocking layer 6, a first current spreading layer 7, and a first ohmic contact layer 8, where the superlattice 51 includes a quantum well sub-layer 511: InₓGa₁₋ₓN, a stress conversion sub-layer 512: Al_{y}Sc_{1-y}N, a GaN cap layer 513, a stress compensation sub-layer 514: Al_{z}Ga_{1-z}N:Si, and an Al_{b}Ga_{1-b}N cap layer 515.

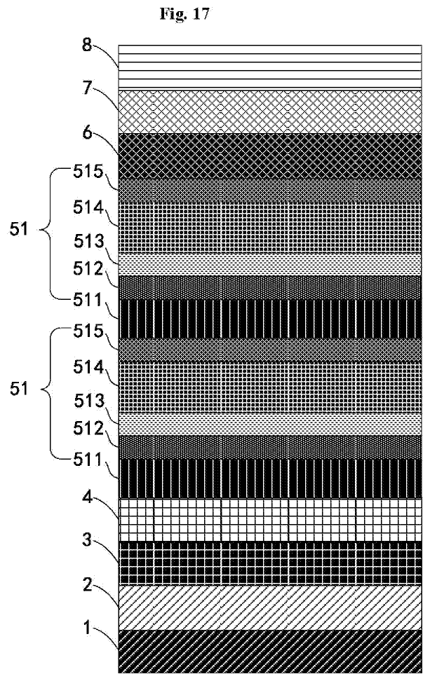

In another example, referring to FIG. 17, the main difference lies in that two superlattices 51 are included compared with FIG. 16, the two superlattices 51 in FIG. 17 are the same in structure, but it should be understood that they may also be provided differently, for example, the superlattices 51 shown in FIG. 2, and FIGS. 4-8 may be flexibly combined, but not limited to, to obtain the epitaxial layer of the light emitting chip of different structures.

Therefore, in the embodiment, the light-emitting chip adopts the epitaxial wafer of the light-emitting chip with better crystal quality and higher light-emitting efficiency, so that the light-emitting efficiency of the light-emitting chip is higher. Especially in some application scenarios, for example, in the process of manufacturing a display panel, a green light-emitting chip and a red light-emitting chip can be set to adopt the light-emitting chip structure provided by the embodiment, and a blue light-emitting chip can adopt a traditional light-emitting chip structure with relatively low light-emitting efficiency. Therefore, the light-emitting efficiencies of the green light-emitting chip, the red light-emitting chip and the blue light-emitting chip are basically kept consistent, and the overall display effect is further improved.

It should be understood that the application of the present disclosure is not limited to the examples described above, and modifications or variations may be made in light of the above description by those of ordinary having ordinary skill in the art, all of which are intended to fall within the scope of protection of the appended claims.

What is claimed is:

1. An epitaxial wafer of a light-emitting chip, the epitaxial wafer comprising: a light-emitting layer of an active region, wherein the light-emitting layer of the active region comprises at least one superlattice, each superlattice comprising:
a quantum well sub-layer; and
a stress conversion sub-layer, which is formed on the quantum well sub-layer and enables the quantum well sub-layer to be converted into tensile strain from compressive strain, wherein the stress conversion sub-layer and the quantum well sub-layer form a two-dimensional electron gas.

2. The epitaxial wafer of the light-emitting chip according to claim 1, wherein the quantum well sub-layer comprises an InₓGa₁₋ₓN sub-layer; and
the stress conversion sub-layer comprises an Al_{y}Sc_{1-y}N sub-layer formed on the InₓGa₁₋ₓN sub-layer.

3. The epitaxial wafer of the light-emitting chip according to claim 2, wherein in the InₓGa₁₋ₓN sub-layer, a value of x satisfies a following condition:
1240=λ×(3.42−2.65×(1−x)−2.4×x×(1−x)), wherein λ is a light-emitting wavelength;
in the Al_{y}Sc_{1-y}N sub-layer, a value of y is greater than 0 and smaller than 1.

4. The epitaxial wafer of the light-emitting chip according to claim 3, wherein λ is greater than or equal to 400 nm and smaller than or equal to 740 nm.

5. The epitaxial wafer of the light-emitting chip according to claim 2, wherein the Al_{y}Sc_{1-y}N sub-layer has a thickness greater than or equal to 0.5 nm and smaller than or equal to 3 nm.

6. The epitaxial wafer of the light-emitting chip according to claim 2, wherein the InₓGa₁₋ₓN sub-layer has a thickness greater than 1 nm and smaller than or equal to 5 nm.

7. The epitaxial wafer of the light-emitting chip according to claim 2, wherein the superlattice further comprises a stress compensation sub-layer formed on the Al_{y}Sc_{1-y}N sub-layer.

8. The epitaxial wafer of the light-emitting chip according to claim 7, wherein the stress compensation sub-layer comprises an Al_{z}Ga_{1-z}N:Si sub-layer, concentration of Si is in a range from 0 cm⁻³ to 1×10¹⁸ cm⁻³, and z is greater than or equal to 0 and smaller than or equal to 0.4.

9. The epitaxial wafer of the light-emitting chip according to claim 7, wherein the Al_{z}Ga_{1-z}N:Si sub-layer has a thickness greater than 6.5 nm and smaller than or equal to 20 nm.

10. The epitaxial wafer of the light-emitting chip according to claim 8, wherein the superlattice further comprises a GaN cap layer formed between the Al_{y}Sc_{1-y}N sub-layer and the Al_{z}Ga_{1-z}N:Si sub-layer.

11. The epitaxial wafer of the light-emitting chip according to claim 10, wherein the GaN cap layer has a thickness greater than or equal to 1 nm and smaller than or equal to 3 nm.

12. The epitaxial wafer of the light-emitting chip according to claim 8, wherein the superlattice further comprises an Al_{b}Ga_{1-b}N cap layer formed on the Al_{z}Ga_{1-z}N:Si sub-layer, and b is greater than or equal to 0 and smaller than z.

13. The epitaxial wafer of the light-emitting chip according to claim 12, wherein the Al_{b}Ga_{1-b}N cap layer has a thickness greater than or equal to 1 nm and smaller than or equal to 3 nm.

14. The epitaxial wafer of the light-emitting chip according to claim 2, wherein the light-emitting layer of the active region comprises at least two superlattices, and the at least two superlattices are sequentially stacked from bottom to top.

15. A light-emitting chip, comprising the epitaxial wafer of the light-emitting chip according to claim 1, wherein the epitaxial wafer of the light-emitting chip further comprises a first current spreading layer and a second current spreading layer respectively formed on an upper side and a lower side of the light-emitting layer of the active region, and the light-emitting chip further comprises a first electrode and a second electrode respectively electrically connected to the first current spreading layer and the second current spreading layer.

16. The light-emitting chip according to claim 15, wherein the epitaxial wafer of the light-emitting chip further comprises a substrate located below the second current spreading layer, and a stress control layer formed between the substrate and the second current spreading layer.

17. A method for manufacturing the epitaxial wafer of the light-emitting chip according to claim 1, comprising: growing a light-emitting layer of an active region, wherein growing the light-emitting layer of the active region comprises growing at least one superlattice by the following operations:
growing the quantum well sub-layer in a reaction chamber; and
growing the stress conversion sub-layer on the quantum well sub-layer.

18. The method for manufacturing the epitaxial wafer of the light-emitting chip according to claim 17, wherein the quantum well sub-layer comprises an InₓGa₁₋ₓN sub-layer, and the stress conversion sub-layer comprises an Al_{y}Sc_{1-y}N sub-layer; and
growing the stress conversion sub-layer on the quantum well sub-layer comprises:
injecting an N source into the reaction chamber, and alternately injecting a Sc source and an Al source according to a set proportion.

19. The method for manufacturing the epitaxial wafer of the light-emitting chip according to claim 18, wherein
when growing the stress conversion sub-layer on the quantum well sub-layer, temperature in the reaction chamber is greater than or equal to 650° C. and smaller than or equal to 1250° C.

20. The method for manufacturing the epitaxial wafer of the light-emitting chip according to claim 18, wherein
the Sc source comprises Cp₃Sc.
